(19) United States
(12) Patent Application Publication
(10) Pub. No.: US 2026/0262516 A1
(43) Pub. Date: Sep. 3, 2026

(54) COMPRESSION INTERPOSER AND INTERCONNECT SYSTEM

(71) Applicant: Samtec, Inc., New Albany, IN (US)

(72) Inventors: Troy B. HOLLAND, New Albany, IN (US); Michael R. MENKHAUS, New Albany, IN (US)

(21) Appl. No.: 18/881,954

(22) PCT Filed: Jul. 7, 2023
(86) PCT No.: PCT/US2023/027085

§ 371 Date: Jan. 7, 2025

Related U.S. Application Data
(60) Provisional application No. 63/359,635, filed on Jul. 8, 2022.

(51) Int. Cl. H10W 70/62; H01R 4/48

(52) U.S. Cl. CPC H10W 70/644; H01R 4/4863

(57) ABSTRACT

An interposer, such as a compressible interposer, that can include a spring, such as a coil spring, which can at least partially circumscribe a compressible center. The interposer can be used in place of or as a substitute for a solder-based surface mount technology (SMT) solder ball or a solder charge. The interposer can be attached with other interposers to a carrier to form an LGA-LGA type of interposer.

### CROSS REFERENCE TO RELATED APPLICATIONS

This application claims the benefit of U.S. Patent Application No. 63/359,635 filed on Jul. 8, 2022. The entire contents of this application are hereby incorporated by reference.

### BACKGROUND OF THE INVENTION

### 1. Field of the Invention

The present invention relates to interposers. More specifically, the present invention relates to compression interposers that can be made using an additive manufacturing process.

### 2. Description of the Related Art

FIG. 1 shows a known ZRAY brand interconnect 100, commercially available from Samtec, Inc., New Albany, IN. The interconnect 100 is a low-profile, high-density one-piece array with compression contacts 101 on two sides. The compression contacts 101 can be made of beryllium copper (BeCU), but other suitable materials are possible. In alternative configurations, the contacts 101 can be replaced with solder balls on two sides, or the contacts 101 can be replaced with solder balls on only one side, while still using the compression contacts 101 on the other side. Compression contacts 101 are defined in two arrays, although any number of arrays and size of arrays are possible. The high-speed interconnects 100 include an optional substrate in which the compression contacts 101 are embedded.

### SUMMARY OF THE INVENTION

According to an embodiment of the present invention, an interposer, as described herein, can include a first contact surface and a second contact surface opposed to the first surface. Teeth can be defined on the first contact surface and/or the second contact surface. A spring can connect or be connected to the first and the second contact surfaces. A compressible center can be located within the spring such that the compressible center is at least partially circumscribed by the spring.

The interposer can include a first disc that can define the first contact surface. The interposer can include a second disc that can define a second contact surface. A height of the interposer is about 1 mm or less, such as approximately 1 mm, approximately 0.9 mm, approximately 0.8 mm, approximately 0.7 mm, approximately 0.6 mm, approximately 0.5 mm, approximately 0.4 mm, approximately 0.3 mm, approximately 0.2 mm, approximately 0.1 mm, approximately 0.01 mm, and/or approximately 0.001 mm, within manufacturing and/or measurement tolerances. A height of each tooth of the teeth can be about 10 μm or less, such as between greater than zero μm and approximately 10 μm. A diameter of a coil of the spring can be about 7 μm-about 18 μm. A height of each tooth of the teeth can be about 1%—about 2% of a height of the interposer.

Each of the teeth can have or can define a conical shape. The interposer can include a light-cured photopolymer that is completely or selectively metallized. The interposer can include a conductive additive. The spring can be a coil spring. A diameter of the spring can increase from a top of the spring to a middle of the spring and can decrease from the middle of the spring to a bottom of the spring. The first diameter of a first portion of the compressible center that is connected to the first contact surface is smaller than a second diameter of a second portion of the compressible center that is connected to the second contact surface. The compressible center can include a solid body. The compressible center can include a hollow cylinder with slats and slits between the slats. The spring and/or the compressible center can be electrically conductive. The interposer can be a 3D-printed interposer. The spring can be configured to cause the first contact surface and/or the second contact surface to rotate when the interposer is compressed.

According to an embodiment of the present invention, an interconnect system can include a carrier of an array of interposers according to various other embodiments of the present invention located in the carrier.

According to an embodiment of the present invention, an interposer can include a first contact surface and a second contact surface opposed to the first surface. A spring can be connected between or can connect the first and the second contact surfaces. A compressible center can be at least partially circumscribed by the spring.

The spring can be a compression spring. The spring can be a barrel spring or beehive spring. The interposer can be printed using a photopolymer, a metal or metal alloy, or both a photopolymer and either a metal or metal alloy. The interposer can be printed during a single print operation. The first contact surface can further include a first plurality of teeth. The second contact surface can further include a second plurality of teeth. The compressible center can define at least one slit. A carrier and an interposer included in the carrier with an array of other interposers can define an interconnect system. The spring can be configured to cause the first contact surface and/or the second contact surface to rotate when the interposer is compressed.

An electrical connector, such a compression mount connector, can be devoid of solder balls and/or press-fit tails and/or SMT J-leads. A contact pad can be carried by the electrical connector. An interposer can be in physical contact, in electrical contact, or in both physical and electrical contact with the contact pad. An interposer can be in physical contact, in electrical contact, or in both physical and electrical contact with the respective contact pad.

According to an embodiment of the present invention, an interconnect system includes an integrated circuit or processor connected to the interposer of one of the various other embodiments of the present invention.

The integrated circuit or processor can include a contact pad. The interposer can be in physical contact, in electrical contact, or in both physical and electrical contact with the contact pad. The interconnect system can further include a carrier including the interposer and additional interposers that are arranged in an array.

A chip or CPU can be devoid of solder balls and/or press-fit tails and/or SMT J-leads. The chip or CPU can further include a contact pad carried by the chip or CPU. The chip or CPU can further include an interposer in physical contact, in electrical contact, or in both physical and electrical contact with the contact pad.

An interconnect system can include a carrier and a longitudinally compressible interposer that is devoid of one or more of a stamped electrical conductor, a single strand of wire compressed into a cylindrical shape, a cantilevered mating conductor, and a cantilevered mounting conductor.

The longitudinally compressible interposer can be made from a cured polymer or cured photopolymer.

An interconnect system can include a carrier and a longitudinally compressible, cured polymer or cured photopolymer interposer that, in cross-section, defines at least one circular or elliptical shape.

The longitudinally compressible interposer can be made from an electrically insulative material. The longitudinally compressible interposer can further include an electrically conductive material.

The above and other features, elements, characteristics, steps, and advantages of the present invention will become more apparent from the following detailed description of preferred embodiments of the present invention with reference to the attached drawings.

### BRIEF DESCRIPTION OF THE DRAWINGS

FIG. 1 shows a known interconnect with compression contacts located on opposing surfaces.

FIG. 2 shows an interposer with a spiral spring and a compressible center.

FIG. 3 is a close-up view of one end of the interposer of FIG. 2.

FIGS. 4 and 5 are sectional views of the interposer of FIG. 2.

FIG. 6 shows the interposer of FIG. 2 without a spiral spring.

FIG. 7 shows a carrier with an array of interposers.

FIG. 8 shows an integrated circuit or processor that can be used with the carrier of FIG. 7.

FIG. 9 shows an integrated circuit or processor of FIG. 8 attached to the carrier of FIG. 7.

### DETAILED DESCRIPTION OF PREFERRED EMBODIMENTS

FIG. 2-6 show an interposer 10 that can include a first disc 11, a second disc 12, a spring 13 connecting the first and the second discs 11, 12, and a compressible or compliant center 14. The first disc 11 can include a contact surface 11a, and the second disc 12 can include a contact surface 12a. Teeth 15 can be included on the first contact surface 11a and/or the second contact surface 12a. The height of the interposer 10 can be about 1 mm or less (but greater than zero millimeters), at least approximately 1 mm, greater than 1 mm, etc. and the height of the teeth 15 can be about 10 μm or less, and the diameter of a coil of the spring can be about 7 μm—about 18 μm, within manufacturing and/or measurement tolerances. The height of the teeth can be about 1%—about 2% the height of the interposer 10. The height of the teeth can be chosen to provide sufficient penetration into a mating surface to provide sufficient or good signal and/or conductivity properties. For example, if the mating surface includes a base layer, a plating layer, and an unwanted oxide or debris layer, the height of the teeth can be chosen to penetrate into the plating layer or just through the unwanted oxide or debris layer but to and/or through the plating layer and/or not into the base layer. Instead of including teeth or in addition to including teeth, the spring 13 can be configured to cause the first disc 11 and/or the second 12 to rotate as the interposer 10 is compressed.

The interposer 10 can be made from a material that can be deposited by an additive manufacturing process, such as a three-dimensional (3D) printing process. The interposer 10 can be made in a single 3D printing process or in multiple processes, one of which is a 3D printing process. The deposited material can be metal or metal alloy or can be a polymer that is then later completely metallized or selectively metallized. Metal or metal alloy material can be deposited using a nozzle or print head to precisely deposit the material upon the preceding layer of material or using a laser or electron beam to selectively melt or partially melt a bed of powdered material. It is also possible to use binder jetting in which a print head selectively deposits a liquid binding agent onto a thin layer of powder particles. As the material cools or is cured, the material forms a three-dimensional object.

The interposer 10 can include a light-cured photopolymer resin that is able to be used in photopolymer processes, including stereolithography (SLA), digital light processing (DLP) processes, 2-photon processes, and holographic processes. The interposer 10 can include additives, for example, particle additives, fiber additives, reactive metal precursors, or conductive polymers. The additives can make the interposer 10 conductive. For example, the interposer 10 can include graphene as an additive. The photopolymer resins include a photoinitiator that reacts with the light to induce polymerization and/or cross-linking. The interposer 10 can be made by an additive manufacturing process, such three-dimensional (3D) printing, which can be implemented by a high-resolution 3D printer having a resolution of about 2 μm, for example, the MICROARCH S230 by BOSTON MICRO FABRICATION. Alternatively, 3D printers of other resolutions may be used, for example, a resolution on the order of about 200 nm.

The first and the second discs 11, 12 can have a circular shape as shown in FIG. 2 or can have any other suitable shape. The first and the second discs 11, 12 can have the same shape as shown in FIG. 2 or can have different shapes.

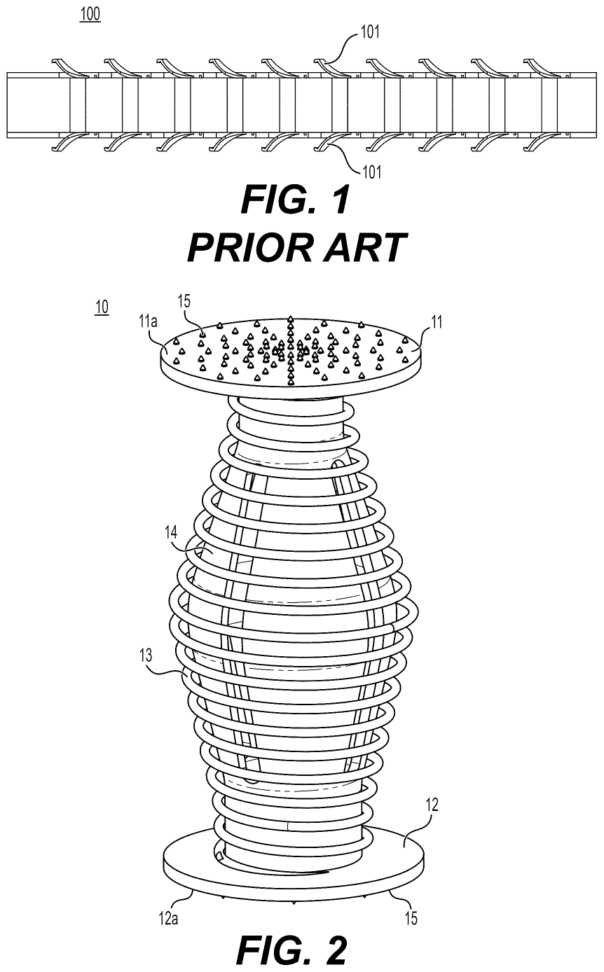

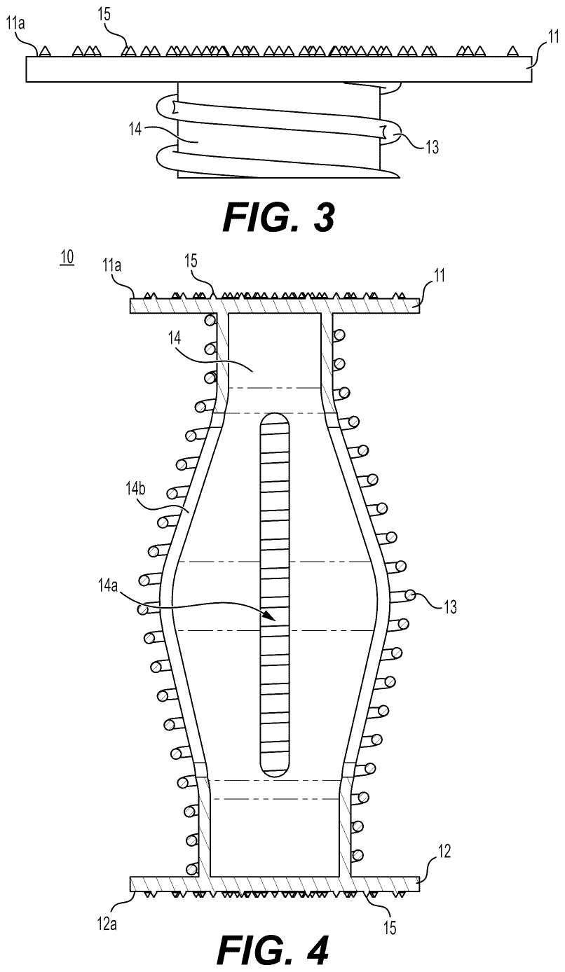

The first and/or the second discs 11, 12 can have teeth 15. Any number, any arrangement, and any shape of teeth 15 can be used. The number, the arrangement, and the shape of the teeth 15 on the first and the second discs 11, 12 can be the same or can be different. FIG. 3 shows teeth 15 arranged along the first surface 11a of the first disc 11. The teeth 15 can be arranged in a radial pattern as shown in FIG. 2 or can have a different arrangement. The teeth 15 can have a conical shape as shown in FIG. 1 or can have any other suitable shape, including, for example, pyramidal. If the teeth 15 are included in the interposer 10, then the teeth 15 can be on only the first contact surface 11a of the first disc 11, can be on only the second contact surface 12a of the second disc 12, or can be on both the first contact surface 11a of the first disc 11 and the second contact surface 12a of the second disc 12. The teeth 15 can be used to pierce any oxide layer and/or any debris layer on the mating surface to which the interposer 10 is mated with, which can eliminate or significantly reduce the need to have contact wipe between the interposer 10 and the mating surface to ensure sufficient electrical contact between the interposer 10 and the mating surface. The teeth can be long enough to pierce any oxide layer and/or any debris layer but short enough not to penetrate a core of a plated surface.

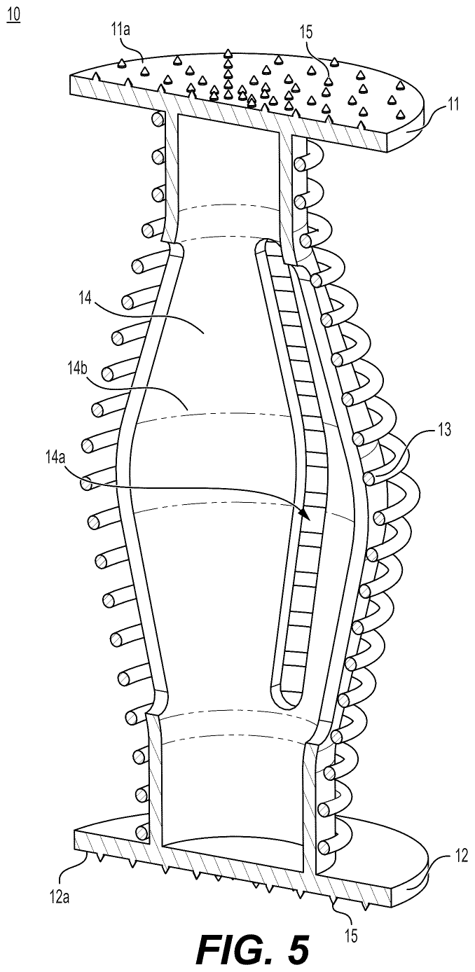

The spring 13 can extend between the first and the second discs 11, 12 and can surround the compressible center 14. FIGS. 4 and 5 are cross-sectional views of the interposer 10 that show how the spring 13 spirals around the compressible center 14. Only the spring 13, only the compressible center 14, or both the spring 13 and the compressible center 14 can be conductive.

The spring 13 can be a coil spring, such as a barrel spring (shown), a beehive spring, or any other spring that can be repeatedly compressed and expanded. As shown in FIG. 2, the spring 13 can have diameter that changes along the length of the spring 13. For example, the diameter of the spring 13 can increase from the top of the spring 13 towards the middle of the spring 13 and can decrease from the middle of the spring 13 to the bottom of the spring 13. Alternatively, the diameter of the spring 13 can increase from top to bottom of the spring 13 or other suitable shape. If diameter of the spring 13 is largest at the bottom of the spring, then the interposer 10. The spring 13 can restrict the bulging or flaring of the compressible center 14. If the spring 13 is conductive, when the spring 13 is fully compressed, adjacent coils of the spring 13 are in physical contact and in electrical contact with each other, which can reduce the electrical resistance of interposer 10.

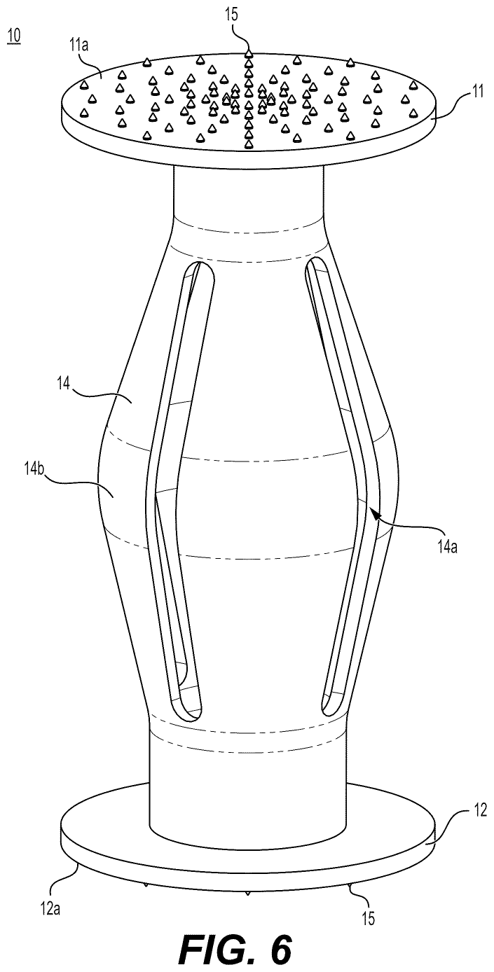

As shown in FIG. 6 that, for clarity, does not include the spring 13, the compressible center 14 can include a hollow cylinder with slits 14a that allow the slats 14b between the slits 14a to bulge or flare out when the interposer 10 is compressed, like a banana adapter. With respect to FIG. 2, when the interposer 10 is compressed in the vertical direction, the slits 14a can bulge or flare out in the horizontal direction. As the interposer 10 is compressed, the slats 14b can come into contact with the spring 13, and if both the spring 13 and the compressible center 14 are conductive, the multiple points of contacts between the spring 13 and slats 14b of the compressible center 14 create multiple electrical paths, which can reduce the resistance of the interposer 10. Alternatively, the compressible center 14 can include a solid body that is compressible so that, when the interposer 10 is compressed in the vertical direction, the solid body bulges out, similar to a pencil eraser. The compressible center 14 can be wider at the bottom than at the top, which can improve the stability of the compressible center 14. For example, the diameter of the top portion of the compressible center 14 that is connected to the first disc 11 or the first contact surface 11a can be smaller than the diameter of the bottom portion of the compressible center 14 that is connected to the second disc 12 or the second contact surface 12a. The spring 13 can be arranged to restrict the bulging of the solid body or compressible center 14 as the photopolymer compresses, such as in non-plastic deformation.

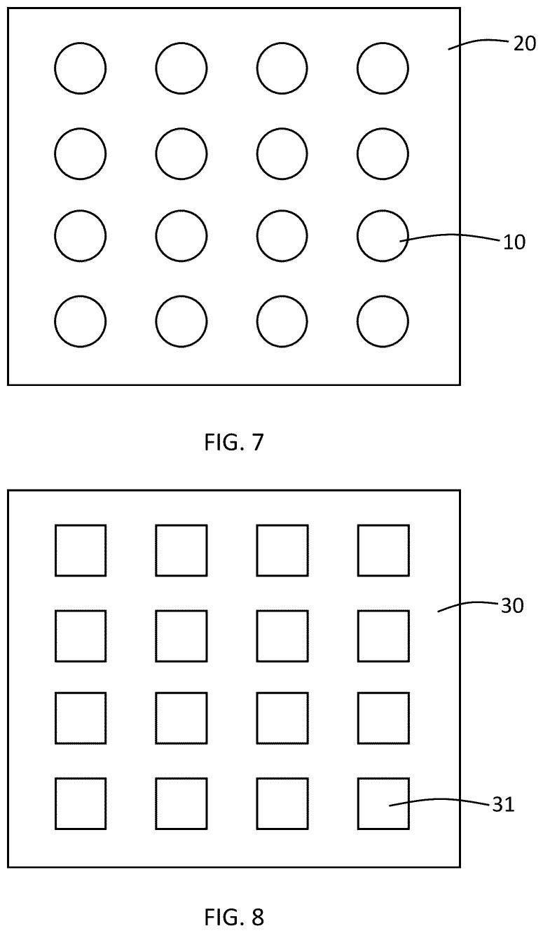

The interposer 10 can be included in a carrier 20, as shown in FIG. 7, that includes an array of interposers 10 to define an interconnect system. Both the carrier 20 and the interposers 10 can be manufactured using additive manufacturing, including, for example, 3D printing. Both the carrier 20 and the interposers 10 can be printed using additive manufacturing during the same print cycle or print period or print operation. A print cycle can include a time period that starts when printing starts and ends when a part or object has been printed, e.g., the carrier 20 with the array of interposers 10. Alternatively, the carrier 20 and the interposers 10 can be manufactured separately and then combined in a different step. In FIG. 7, sixteen interposers 10 are included in a 4×4 array, but any number and any arrangement of interposers 10 can be used.

The interposer 10 can be a substitute for solder balls. Compared to solder balls, an array of interposers 10 can improve co-planarity of the connection because of any one or more of the following reasons: the interposers 10 can be repeatedly held to tolerance during manufacturing; each interposer 10 compresses and does not melt/wick; and each interposer 10 independently compresses by the proper amount to fill in a respective gap or space between a component, such as a chip or a die package or an interconnect and a mating component, such as a printed circuit board, a socket, a mating interconnect, etc. If a respective first gap or first space spanned by one interposer is 1 mm and an immediately adjacent respective second gap or second space spanned by another interposer is 1.5 mm, the one interposer will compress more and the other interposer will compress less, thereby maintaining coplanarity of the connection. Stated another way, unlike solder balls, each interposer 10 can automatically adjust its overall length to compensate for longer or shorter gaps or spaces. Therefore, the interposers 10 can be used in any application that uses a ball grid array (BGA) of solder balls. Although not shown in the figures, the interposer 10 can be included in a connector to provide electrical and physical connection between the connector and a substrate, such as a printed circuit board (PCB), or between a substrate and integrated chip or another similar device. Thus, an electrical connector can be provided that does not use older balls and/or press-fit tails and/or SMT J-leads.

In addition to being used instead of solder balls, the interposer 10 can also function as a “hard ball” BGA by setting the compression distance by the coil bind of the spring 13 or by the compressible center 14 making stiff contact with the spring 13. The repeatability/precision of additive manufacturing process, such as a DLP printer, can achieve coplanarity with very high tolerances, while at the same time, being less sensitive to variability because of the spring 13.

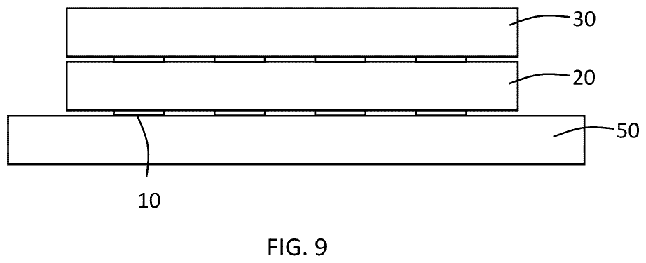

FIG. 8 shows an integrated circuit (IC) or processor 30, and FIG. 9 shows the IC or processor of FIG. 8 attached to the carrier 20. Any IC or processor 30 can be used. For simplicity, FIG. 8 shows the IC or processor 30 with just sixteen contact pads 31 arranged to 4×4 array, but any number and any arrangement of contact pads 31 can be used. FIG. 9 shows an interconnect system in which the interposers 10 in the carrier 20 connect the contact pads 31 of the IC or processor 30 to a substrate 50. By using the interposers 10, the IC or processor 30 can be connected to the substrate without using solder balls and/or press-fit tails and/or SMT J-leads. In some applications, the carrier 20 can be omitted. Any suitable substrate 50, including, for example, a printed circuit board, can be used.

In another embodiment, an interconnect system can include a carrier 20. The interconnect system can further include a longitudinally compressible interposer 10 that is devoid of one or more of a stamped electrical conductor, a single strand of wire compressed into a cylindrical shape, a cantilevered mating conductor, and a cantilevered mounting conductor. The longitudinally compressible interposer 10 can be made from a cured polymer or cured photopolymer.

In another embodiment, an interconnect system can include a carrier 20. The interconnect system can further include a longitudinally compressible, cured polymer or cured photopolymer interposer 10 that, in cross-section, can define at least one of a circular shape or an elliptical shape or an oval shape or a square shape or a rectangular shape or another other suitable shape. The longitudinally compressible interposer 10 can be made from an electrically insulative material. The longitudinally compressible interposer 10 can further include an electrically conductive material.

It should be understood that the foregoing description is only illustrative of the present invention. Various alternatives and modifications can be devised by those skilled in the art without departing from the present invention. Accordingly, the present invention is intended to embrace all such alternatives, modifications, and variances that fall within the scope of the appended claims.

1-40. (canceled)

41. An interposer comprising:
a first contact surface;
a second contact surface opposed to the first contact surface;
a spring connecting the first and the second contact surfaces; and
a compressible center that includes photopolymer and that at least partially circumscribed by the spring, wherein
the spring is not stamped and formed.

42. The interposer of claim 41, wherein the spring is a barrel, beehive, or coil spring.

43. The interposer of claim 41, wherein the interposer is printed using a photopolymer, a metal or metal alloy, or both a photopolymer and either a metal or metal alloy.

44. The interposer of claim 41, wherein the interposer is printed during a single print operation.

45. The interposer of claim 41, wherein
the first contact surface further includes a first plurality of teeth; and
the second contact surface further includes a second plurality of teeth.

46. The interposer of claim 41, wherein the compressible center defines at least one slit.

47. The interposer of claim 41, wherein the spring is configured to cause the first contact surface and/or the second contact surface to rotate when the interposer is compressed.

48. The interposer of claim 41, further comprising:
a first disc defining the first contact surface; and
a second disc defining the second contact surface.

49. The interposer of claim 41, wherein a height of the interposer is about 1 mm or less but greater than 0 mm.

50. The interposer of claim 41, wherein a height of the teeth is about 10 μm or less but greater than 0 μm.

51. The interposer of claim 41, wherein a diameter of a coil of the spring is about 7 μm—about 18 μm.

52. The interposer of claim 41, wherein a height of the teeth is about 1%—about 2% of a height of the interposer.

53. The interposer of claim 41, wherein each of the teeth has a conical shape.

54. The interposer of claim 41, wherein the interposer includes a light-cured photopolymer that is completely or selectively metallized.

55. The interposer of claim 54, wherein the interposer includes a conductive additive.

56. The interposer of claim 41, wherein a first diameter of a first portion of the compressible center that is connected to the first contact surface is smaller than a second diameter of a second portion of the compressible center that is connected to the second contact surface.

57. An interconnect system comprising:
a carrier; and
an array of interposers according to claim 41 located in the carrier.

58. An interconnect system comprising an integrated circuit or processor connected to the interposer of claim 41, wherein
the integrated circuit or processor includes a contact pad, and
the interposer is in physical contact, in electrical contact, or in both physical and electrical contact with the contact pad.

59. The interconnect system of claim 58, wherein the interconnect system is devoid of solder balls and/or press-fit tails and/or SMT J-leads.

60. The interconnect system of claim 58, wherein the interconnect system is devoid of one or more of a stamped electrical conductor, a single strand of wire compressed into a cylindrical shape, a cantilevered mating conductor, and a cantilevered mounting conductor.
